(19) United States
(12) Patent Application Publication
(10) Pub. No.: US 2025/0218977 A1
(43) Pub. Date: Jul. 3, 2025

(54) COAXIAL THROUGH INSULATOR VIA BETWEEN CHIPLETS

(71) Applicant: International Business Machines Corporation, Armonk, NY (US)

(72) Inventors: Manasa MEDIKONDA, Albany, NY (US); Tao Li, Slingerlands, NY (US); Ruilong Xie, Niskayuna, NY (US); Joshua M. Rubin, Albany, NY (US)

(21) Appl. No.: 18/400,458

(22) Filed: Dec. 29, 2023

(51) Int. Cl. H01L 23/552; H01L 23/00; H01L 23/522; H01L 23/538; H01L 25/065

(52) U.S. Cl. CPC H01L 23/552; H01L 23/5226; H01L 23/5384; H01L 25/0652; H01L 24/08; H01L 24/16; H01L 24/32; H01L 24/73; H01L 2224/08145; H01L 2224/16225; H01L 2224/32225; H01L 2224/73204

(57) ABSTRACT

A semiconductor device that includes at least two chiplets separated by an insulating region. The semiconductor device further includes a through insulator via extending through the insulating region. The through insulator via includes a coaxial arrangement of a signal via having ground shielding about a perimeter of the signal via. The ground shielding is continuous from a first face of the insulating region to a second face of the insulating region.

### BACKGROUND

The present invention relates generally to semiconductor devices, and more particularly to a semiconductor devices including through insulator vias (TIV).

Integrated circuits (“ICs”) are incorporated into many electronic devices. Integrated circuit (IC) packaging allows for multiple integrated circuits (ICs) to be vertically stacked in “three-dimensional (3D)” packages in order to save horizontal area on printed circuit boards (PCBs). An alternative packaging technique, referred to as 2.5D packaging, can use an interposer, which may be formed from a semiconductor material such as silicon, for coupling one or more semiconductor die to a printed circuit board (PCB). A plurality of integrated circuits (ICs) or other semiconductor dies, which may be heterogeneous technologies, may be mounted on the interposer.

As the demand for artificial intelligence (AI), high-speed computation (HPC), and powerful computing continues to grow, there is an increasing need to enhance the number of transistors in a single package. However, traditional materials like silicon, commonly used for interposers, are encountering limitations. Insulating substrates, such as glass substrates and dielectric substrates, can offer numerous advantages, including exceptional flatness, high thermal stability, and rigidity. These attributes enable further miniaturization and integration of transistors when compared to silicon substrates.

However, processing using insulating interposer type substrates can present challenges, especially in the context of achieving 2.5D or 3D packaging through the Through-Glass-Via (TGV) technique.

Further, many devices on one or more of the semiconductor die may cause electrical noise and/or create electromagnetic (“EM”) interference by emitting EM emissions. Additionally, through insulator via (TIV) noise coupling in an insulating or glass interposer can cause degradation of the signal quality. Systems based on through insulator vias (TIV) have been determined to be vulnerable to noise coupling because the low loss of the insulator or glass composition interposer, which cannot attenuate the coupling noise.

### SUMMARY

In an embodiment, the present invention provides a through insulator via (TIV) that includes continuous and complete shielding of the electrically conductive features of the through insulator via (TIV) that provides for signal transmission. For example, a coaxial arrangement is provided in which ground shielding is positioned around the signal via. The ground shielding is continuous from a first end of the through insulator via (TIV) to the second end of the through insulator via (TIV). The ground shielding can connect to electrically conductive features on both ends of the through insulator via (TIV). The continuous ground shielding can provide a continuous ground return path for uniform impedance. The coaxial geometry of the ground shielding around the signal, as well as the continuous nature of the ground shielding along the entire height of the signal via, provides a through insulator via (TIV) that can overcome the disadvantages of noise through insulator vias (TIVs) that do not include the continuous shielding of the designs described herein.

In an embodiment, a device is provided that includes two adjacent chiplets separated by an insulating region. A through insulator via (TIV) is present in the insulating regions separating the two adjacent chiplets. The through insulator via (TIV) includes a coaxial arrangement of a signal via having ground shielding about a perimeter of the signal via. The ground shielding is continuous from a first face of the insulating region to a second face of the insulating region.

In an embodiment, the signal via is separated from the ground shielding by a via insulating material. In some embodiments, the insulating region has a first dielectric composition that is different from a composition of a second dielectric composition for the via insulating material.

In some embodiments, the through insulator via (TIV) is connected to a bridge chip that is present on the at least two chiplets.

In some embodiments, the through insulator via (TIV) is in electrical communication with a redistribution layer on at least one of the first and second face of the insulating region. The redistribution layer being may be in electrical communication with one of the at least two chiplets.

In some embodiments, the semiconductor device includes two stacked levels of chiplets and the through insulator via (TIV) is a skip via.

In some embodiments, the through insulator via (TIV) with the ground shielding may be integrated with a power via that does not include ground shielding.

In another embodiment, semiconductor device is provided that includes at least two chiplets separated by an insulating region and a through insulator via (TIV) extending through the insulating region. The through insulator via (TIV) may include a coaxial arrangement of a signal via of a first metal composition having ground shielding of a second metal composition about a perimeter of the signal via. In some embodiments, the first metal composition is different than the second metal composition. In some embodiments, the ground shielding is continuous from a first face of the insulating region to a second face of the insulating region.

In some embodiments, the signal via is separated from the ground shielding by a via insulating material. In some embodiments, the insulating region has a composition that is different from the composition of the via insulating material.

In some embodiments, the through insulator via (TIV) is connected to a bridge chip that is present on the at least two chiplets. In some embodiments, the through insulator via is in electrical communication with a redistribution layer on at least one of the first and second face of the insulating region. In some embodiments, the redistribution layer is in electrical communication with one of the at least two chiplets.

In some embodiments, the semiconductor device includes a plurality of chiplets that are present on different levels. In some embodiments, the different levels can include two stacked levels of chiplets, and the through insulator via (TIV) is a skip via.

In some embodiments, the through insulator via (TIV) having the ground shielding may be integrated with a power via that does not include ground shielding.

In another embodiment, a semiconductor device is provided that includes at least two chiplets separated by an insulating region. The semiconductor device also includes a through insulator via (TIV) extending through the insulating region. The through insulator via (TIV) includes a coaxial arrangement of a signal via having ground shielding about a perimeter of the signal via. In some embodiments, the signal via and the ground shield each have a same metal composition. The ground shielding is continuous from a first face of the insulating region to a second face of the insulating region.

In an embodiment, the signal via is separated from the ground shielding by a via insulating material. In an embodiment, the insulating region has a composition that is different from the composition of the via insulating material.

In an embodiment, the through insulator via is connected to a bridge chip that is present on the at least two chiplets.

In some embodiments, the through insulator via is in electrical communication with a redistribution layer on at least one of the first and second face of the insulating region. The redistribution layer is in in electrical communication with one of the at least two chiplets.

In some embodiments, the at least two chiplets including a plurality of chiplets that are present on different levels. In an embodiment, the different levels can include two stacked levels of chiplets and the through insulator via is a skip via.

In an embodiment, the at least two chiplets includes two stacked levels of chiplets and the through insulator via is a skip via.

### BRIEF DESCRIPTION OF DRAWINGS

The disclosure will provide details in the following description of preferred embodiments with reference to the following figures wherein:

FIG. 1 is a side cross-sectional view of an electrical device including a through insulator via (TIV) present in an insulating region separating two adjacent chiplets, wherein the through insulator via (TIV) includes a coaxial arrangement of a signal via having ground shielding about a perimeter of the signal via, wherein the ground shielding is continuous, in accordance with an embodiment of the present invention;

FIG. 2 is a top down view of the through insulator via (TIV) that is depicted in FIG. 4, in accordance with an embodiment of the present invention;

FIG. 3 is a side cross-sectional view of a through insulator via (TIV) that is a skip via, in accordance with an embodiment of the present invention;

FIG. 4 is a side cross-sectional view of a chiplet, in accordance with an embodiment of the present invention;

FIG. 5 is a side cross-sectional view of a bridge chip, in accordance with an embodiment of the present invention;

FIG. 6 is a side cross-sectional view illustrating two chiplets separated by an insulating region, in accordance with an embodiment of the present invention;

FIG. 7 is a side cross-sectional view illustrating carrier attachment to the structure depicted in FIG. 6, in accordance with an embodiment of the present invention;

FIG. 8 is a side cross-sectional view of coaxial through dielectric via patterning for a through insulator via (TIV) having a signal via and ground shielding each having the same composition, in accordance with an embodiment of the present invention;

FIG. 9 is a side cross-sectional view illustrating filling the via openings with electrically conductive material for the signal via and the ground shielding of the through insulator via (TIV), in accordance with an embodiment of the present invention;

FIG. 10 is a side cross-sectional view depicting forming an opening for a through insulator via (TIV), in accordance with an aspect of the present invention;

FIG. 11 is a side cross-sectional view illustrating metal deposition into a via opening for a through insulator via, in which the metal being deposited provides ground shielding; in accordance with an embodiment of the present invention;

FIG. 12 is a side cross-sectional view illustrating forming a liner for the via dielectric on the ground shielding; in accordance with an embodiment of the present invention; and

FIG. 13 is a side cross-sectional view of a metal deposition to form the signal via, wherein the signal via may have a different metal composition than the metal composition of the ground shielding, in accordance with an embodiment of the present invention.

### DETAILED DESCRIPTION OF PREFERRED EMBODIMENTS

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure. For purposes of the description hereinafter, the terms “upper”, “lower”, “right”, “left”, “vertical”, “horizontal”, “top”, “bottom”, and derivatives thereof shall relate to the embodiments of the disclosure, as it is oriented in the drawing figures. The term “positioned on” means that a first element, such as a first structure, is present on a second element, such as a second structure, wherein intervening elements, such as an interface structure, e.g. interface layer, may be present between the first element and the second element. The term “direct contact” means that a first element, such as a first structure, and a second element, such as a second structure, are connected without any intermediary conducting, insulating or semiconductor layers at the interface of the two elements.

In an embodiment, the present invention provides a through insulator via (TIV) that includes continuous and complete shielding of the electrically conductive signal transmission features of the through insulator via (TIV).

In accordance with some embodiments, the ground shielding is continuous from one end of the through insulator via to the second end of the through insulator via (TIV). The ground shielding can connect to electrically conductive features on both ends of the through insulator via (TIV). This can provide a continuous ground return path for uniform impedance. The coaxial geometry of the ground shielding around the signal via, as well as the continuous nature of the ground shielding along the entire height of the signal via, provides a through insulator via (TIV) that can overcome the disadvantages of noise coupling in prior through insulator vias having insufficient shielding.

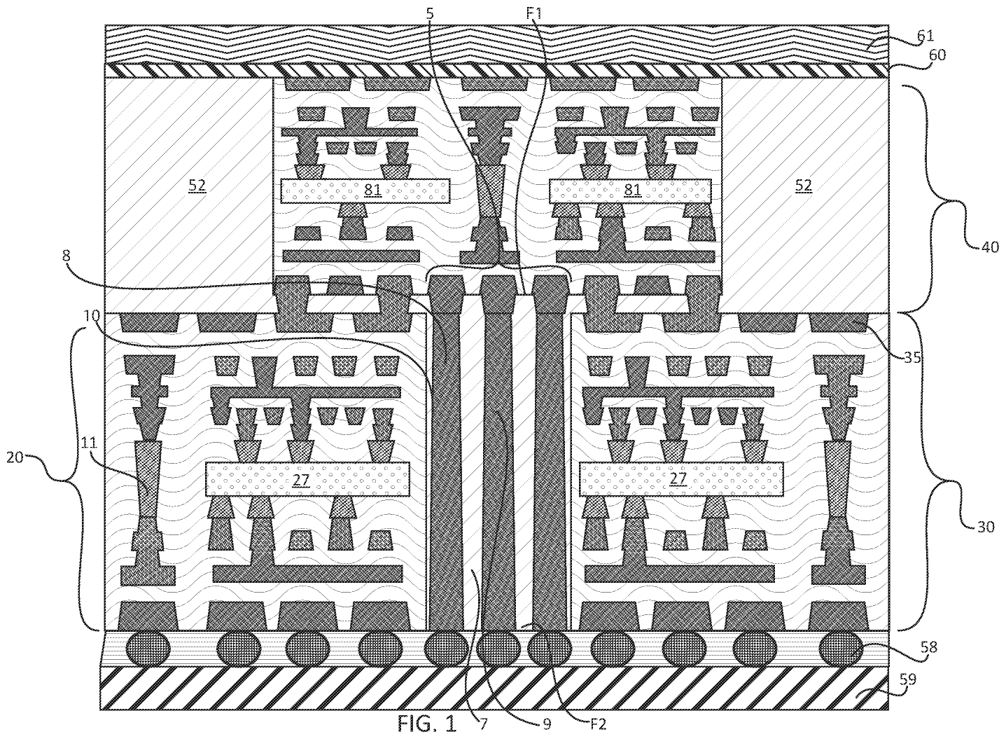

FIG. 1 illustrates an electrical device including a through insulator via (TIV) 10 present in an insulating region 5 separating a first chiplet 20 from a second chiplet 30. More particularly, the insulating region 5, the first chiplet 20 and the second chiplet 30 are on the same level. A “chiplet” is an integrated circuit (IC) that contains a subset of functionality. In some embodiments, the chiplets are designed to be combined with other chiplets with an interposer/bridge in a single package. The first chiplet 20 is present on a first side of the insulating region 5, and the second chiplet 30 is present on second side of the insulating region 5.

FIG. 1 also illustrates an embodiment of the through insulator via (TIV) 10. The through insulator via (TIV) 10 may have a coaxial arrangement of a centrally positioned signal via 9 having ground shielding 8 about a perimeter of the signal via 9.

A “through insulator via (TIV)” is a vertical metal containing via passing completely through an insulating material. In the embodiment depicted in FIG. 1, the insulating material that the through insulator via (TIV) 10 extends through may be the insulating region 5 that is present between and separating the first chiplet 20 from the second chiplet 30.

The insulating material that the through silicon via (TIV) is positioned through may be a glass type dielectric. However, the insulating material that the through insulator via (TIV) extends through is not intended to be limited to only glass type compositions, as any insulating material through which a via can extend is suitable for providing the insulating material that the through silicon via (TIV) is present in. For example, the insulator that the through silicon via (TIV) extends through, e.g., the insulator composition for the material that is present in the insulating region 5, may be aluminosilicate glass, borosilicate glass, fused silica or a combination thereof. Other insulators may include oxides, nitrides or oxynitride containing materials.

The through insulator via 10 includes a signal via 9 and ground shielding 8 in a coaxial arrangement. The coaxial arrangement includes at least two concentric conductors separated by an insulator. The signal via 9 may be the centrally positioned conductor, and the ground shielding 8 may surround, e.g., encircle, the signal via 9. The signal via 9 and the ground shielding 8 may have the composition of an electrically conductive material. For example, the signal via 9 and the ground shielding 8 may each have the composition of any elemental metal, such as copper (Cu), aluminum (Al), titanium (Ti), tantalum (Ta), tungsten (W) and combinations thereof. In some embodiments, the signal via 9 and the ground shielding 8 may have the same composition metal. In other embodiments, the signal via 9 and the ground shielding 8 have different composition metals.

A via insulating material 7 may be present between and separating the signal via 9 and the ground shielding 8. The via insulating material 7 may have a dielectric composition. For example, the via insulating material 7 may have a composition that includes an oxide, e.g., silicon oxide, a nitride, e.g., silicon nitride, or an oxynitride material. In some examples, the via insulating material 7 can have a different composition than the insulating material composition for the material of the insulating region 5.

In some embodiments, the ground shielding 8 is continuous from a first face F1 of the insulating region 5 to a second face F2 of the insulating region 5. In some examples, the term “continuous” when describing the ground shielding means that that the shielding material layer is completely free of breaks or openings along an entirety of the height of ground shielding 8 that extends from the first face F1 to the second face F2 of the insulating region 5.

The first face F1 and the second face F2 of the insulating region 5 can included an interface to electrically conductive features of a bridge chip 40, e.g., stacked bridge chip. A bridge chip 40 includes circuitry, as well as active devices, that can provide for electrical communication between the first chiplet 20 and the second chiplet 30. FIG. 1 illustrates how the bridge chip 40 extends from a portion of the first chiplet 20 across the insulator region 5 to portion of the second chiplet 30.

In some embodiments, the through insulator via (TIV) 10 having the coaxial arrangement of the signal via 9 and the ground shielding 8 may be integrated with a power via 11 that does not include ground shielding.

In some embodiments, the interconnects of metal between the first chiplet 20 the bridge chip 40 and the second chiplet 30, as well as the through insulator via 10, provides for electrical communication between the elements. In some embodiments, the interconnects at the interfaces of the bridge chip 40, the first chiplet 20 and the second chiplet 30 are provided by redistribution layers 35. Redistribution layers (RDLs) are the metal interconnects that electrically connect one part of the semiconductor package to another. In one example, the through insulator via (TIV) 10 is in electrical communication with a redistribution layer 35 on the face F1 of the insulating region 5. In one example, the redistribution layer 35 is in electrical communication with the first chiplet 20 and the second chiplet 30.

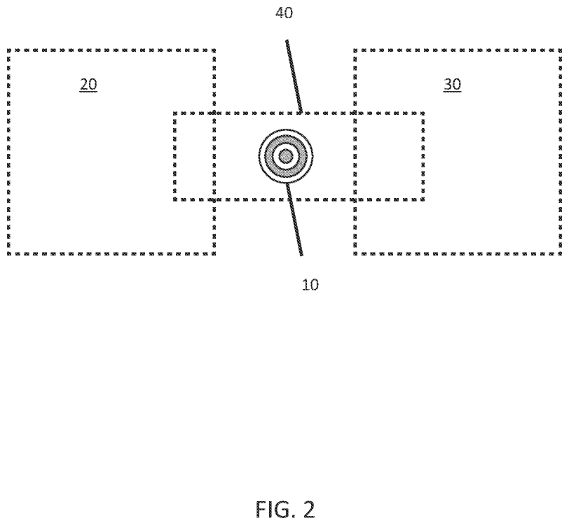

FIG. 2 is a top down view further illustrating the bridge chip 40 being positioned on a portion of the first chiplet 20 and a portion of the second chiplet 30. FIG. 2 further depicts that the through insulator via (TIV) 10 is in contact with the bridge chip 40 and is centrally positioned thereon.

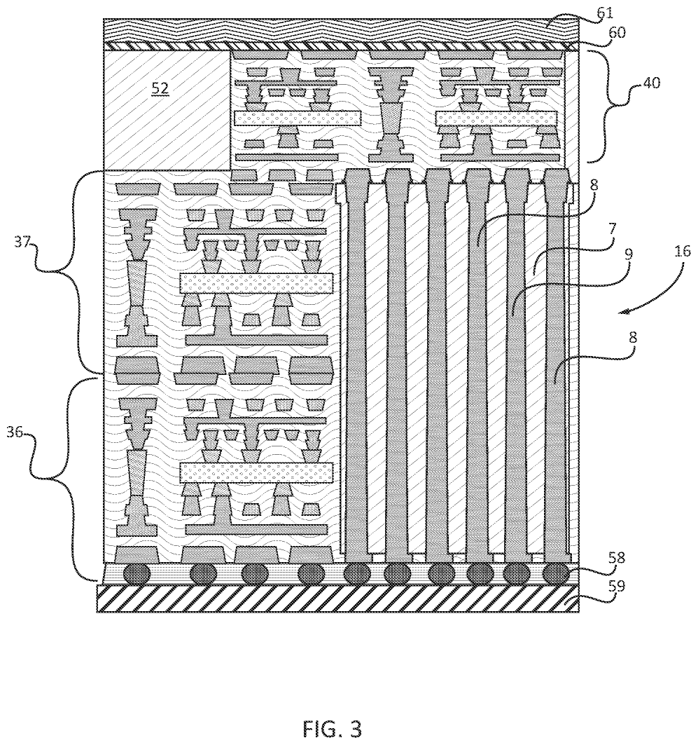

FIG. 3 illustrates one embodiment of a through insulator via (TIV) that is a skip via 16. A skip via 16 is a connection over at least two levels that directly connects the bottom level with an upper level electrically without connecting the intermediate level. In some embodiments, a plurality of chiplets are present in two stacked level, e.g., first level 36 and second level 37. The skip via 16 is not in electrical communication with the first level 36. The skip via 16 is in electrical communication with the second level 37 through the bridge chip 40. Similar to the through insulator via (TIV) 10 that is depicted in FIG. 1, the skip via 16 is also a through insulator type via that includes a coaxial arrangement of a signal via 9 having ground shielding 8 encircling the perimeter of the signal via 9. The signal via 9 and the ground shielding 8 of the skip via 16 may also be separated by a via insulating material 7. As noted, the skip via 16 depicted in FIG. 3 is similar to the through insulator via (TIV) that is depicted in FIG. 1. The skip via 16 may include a signal via 9 in a coaxial arrangement with ground shielding 8 similar to the coaxial arrangement of these elements in the through insulator via (TIV) that is depicted in FIG. 1. Elements depicted in FIG. 3 having the same reference numbers as elements depicted in FIG. 1 may be described by the description of those elements in the description of FIG. 1 that is provided above.

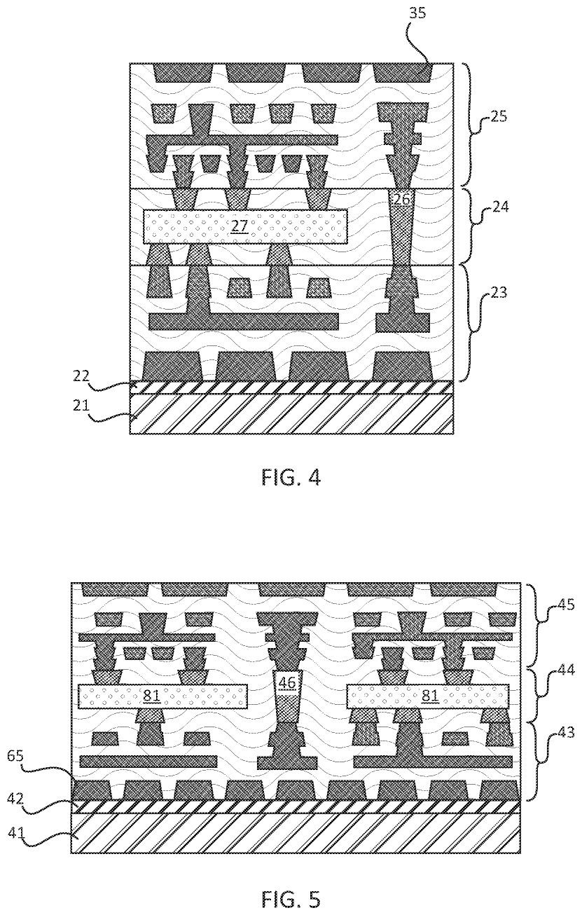

The structures depicted in FIGS. 1-3 are now described with reference to FIGS. 4-13, which illustrate an embodiment of methods for forming structures including through insulator vias (TIV) 10. It is noted that the method depicted in FIGS. 4-13 illustrate only one example of a method for forming the structures depicted in FIGS. 1-3. It is noted that the present disclosure is not intended to be limited to only the method depicted in FIGS. 4-13.

FIG. 4 illustrates an embodiment of a first chiplet 20. It is noted that the first chiplet depicted in FIG. 4 is suitable for the second chiplet 30, as the first chiplet 20 and the second chiplet 30 may be similar. However, the first chiplet 20 and the second chiplet 30 may be different. Chiplets are designed to be combined with other chiplets with an interposer/bridge in a single package. In some embodiments, the first chiplet 20 may include a chiplet carrier 21, an chiplet bonding layer 22, a chiplet backside power distribution network level 23, a chiplet active device level 24 and a chiplet back end of the line level 25.

The chiplet carrier 21 provides support for the chiplet 20 through processing that can include layer transfer. The chiplet carrier 21 may be a silicon substrate. However, other substrate types may also be applicable for the chiplet carrier 21. The chiplet carrier 21 may be engaged to the chiplet backside power distribution network level 23 through the chiplet bonding layer 22, which can be an oxide containing layer. Backside power delivery refers to the technique of routing power supply lines on the backside of a semiconductor chip or integrated circuit (IC) instead of the traditional frontside. The chiplet backside power distribution network level 23 may include a plurality of metal lines and vias formed through interlevel dielectric layers.

The chiplet active device level 24 is present on the chiplet backside power distribution network 23. The chiplet active device level 24 may be formed using front end of the line (FEOL) processing. The chiplet active device level 24 may include the active devices for the chiplet 20. The term “active device” refers to a devices that include, but are not limited to transistors, resistors and capacitors. In some embodiments, the active devices are formed on a semiconductor substrate 27 that is integrated into the first chiplet 20. Middle of the line (MOL) processing may be employed to form frontside contacts to the active devices in the chiplet active device level 24. The chiplet back end of the line level 25 is present on the chiplet active device level 24.

The chiplet back end of the line (BEOL) level 25 includes metal lines and vias that may be in electrical communication with the frontside contacts to the active devices.

The process sequence that is used for forming the metal lines and vias is a back end of the line (BEOL) process. In some embodiments, an interlevel dielectric layer is first deposited and then etched to form via openings to the underlying contacts. Thereafter, the via openings are then filled with an electrically conductive material, such as a metal, e.g., copper, to provide vias. Thereafter, a deposition, pattern and fill sequence is repeated to forms lines. This may be referred to as a single damascene method for forming lines and vias. However, dual damascene sequences are also applicable. The sequence of deposition, pattern and etch are repeated as many times as needed to form each level of metal lines and vias. Still referring to FIG. 4, in an embodiment, a chiplet through insulator via 26 that can provide electrical communication between the frontside metal lines and vias and the backside metal lines and vias. The top of the back end of the line level 25 may include a chiplet redistribution layer 35.

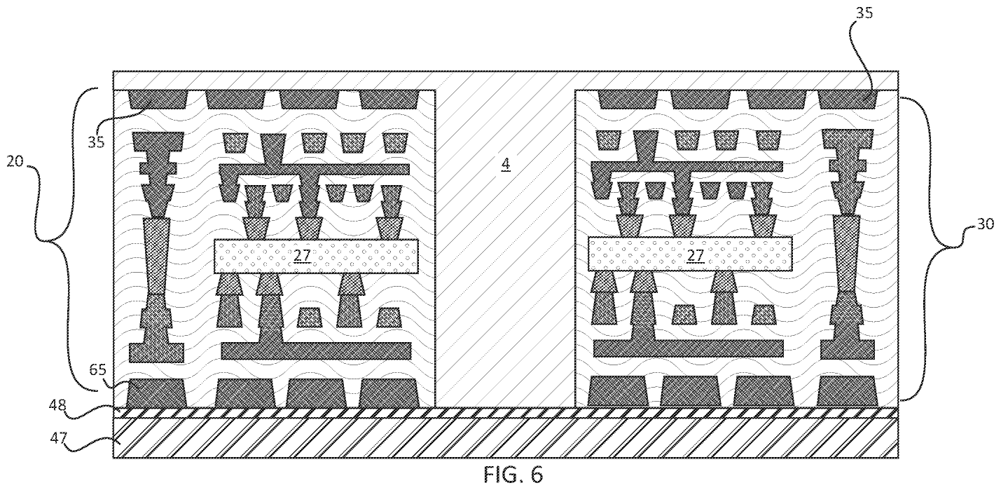

FIG. 5 illustrates an embodiment of a bridge chip 40. In some embodiments, a bridge chip 40 includes circuitry, as well as active devices, that can provide for electrical communication between the first chiplet 20 and the second chiplet 30. The bridge chip 40 may include a bridge chip carrier 41. The bridge chip carrier 41 is bonded to a backside metallization layer 43 through a bridge chip bonding layer 42, which may be an oxide. The backside metallization layer 43 may include electrical contacts to a bridge chip active device level 44. The bridge chip active device level 44 may be formed using front end of the line (FEOL) processing. The bridge chip active device level 44 may include the active devices for the bridge chip 40, which can include, but is not limited to transistors, resistors and capacitors. The active devices for the bridge chip device level 44 may be present on bridge chip active device substrate 81. The bridge chip frontside metallization layer 45 is present on the bridge chip active device level 44.

The bridge chip 40 includes one side for interfacing with the first chiplet 20, and a second side for interfacing with the second chiplet 30. An active device region may be present on each side of the bridge chip active device level 44 to communicate with the first chiplet 20 and the second chiplet 30 that corresponds to the side that the active device region is present on.

Still referring to FIG. 5, in an embodiment, a bridge chip through insulator via 46 can provide electrical communication between the frontside and backside metallization layers. In some embodiments, the bridge chip 40 may include a bridge chip redistribution layer 65.

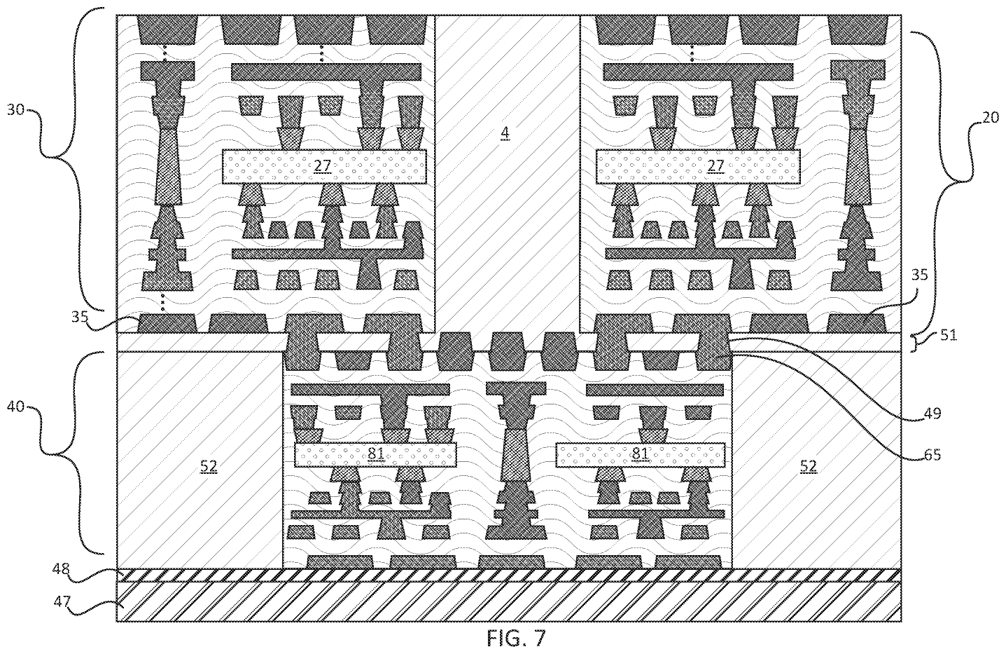

FIG. 6 depicts an embodiment of a first chiplet 20 and a second chiplet 30 being bonded to a package carrier 47 through a bonding pad 48. Prior to bonding to the package carrier 47, the chiplet carrier 21 and chiplet bonding layer 22 may be removed. Dicing operations can reduce the dimensions of the chiplets. The package carrier 47 may be a semiconductor substrate. The first chiplet 20 and second chiplet 30 may be bonded to provide a distance therebetween that is filed with an insulating material to provide the insulating region 5. The insulating region 5 may be filled with multiple layers of dielectric material.

FIG. 6 further illustrates filling the space separating the first chiplet 20 from the second chiplet 30 with a dielectric material 4 that provides the composition of the isolation region 5. In some embodiments, the dielectric material 4 may be deposited using chemical vapor deposition or spin on deposition. Following deposition, a planarization process, such as chemical mechanical planarization (CMP) may be applied.

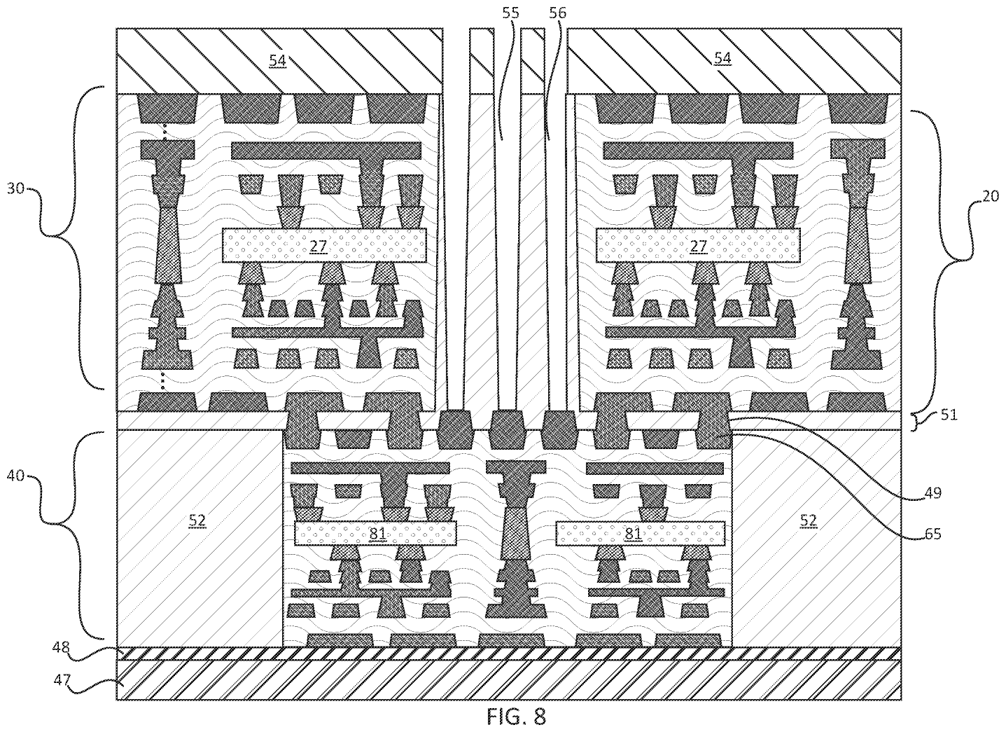

FIG. 7 depicts attachment of the first chiplet 20 and the second chiplet 30 to a bridge chip 40. In some embodiments, a plurality of contacts 49 for a bridge chip connection layer 51 are formed on the upper surface of the structure depicted in FIG. 6. The bridge chip connection layer 51 is formed by depositing a dielectric layer, patterning the dielectric layer using photolithography and etching to provide openings for the plurality of contacts 49, and then filling the openings with an electrically conductive material, such as a metal, for the contacts. Forming the plurality of contacts 49 can further include planarization. In some embodiments, some of the contacts 49 are in direct contact with the electrically conductive features of the chiplet redistribution layer 35 for the first chiplet 20 and the second chiplet 30.

In a following step, the electrically conductive features of the bridge chip redistribution layer 65 may be bonded to the contacts of the bridge chip connection layer 51. Bonding may be provided by thermal bonding processes. In a following step, a dielectric material fill may be deposited, such as an oxide, nitride or oxynitride. The deposition process can include chemical vapor deposition, but this is only one example of a deposition process that is suitable for this stage of the process flow. A planarization process may be applied to dielectric material fill 52, such as chemical mechanical planarization. The planarization process may remove the bridge chip carrier 41 and the bridge chip bonding layer 42.

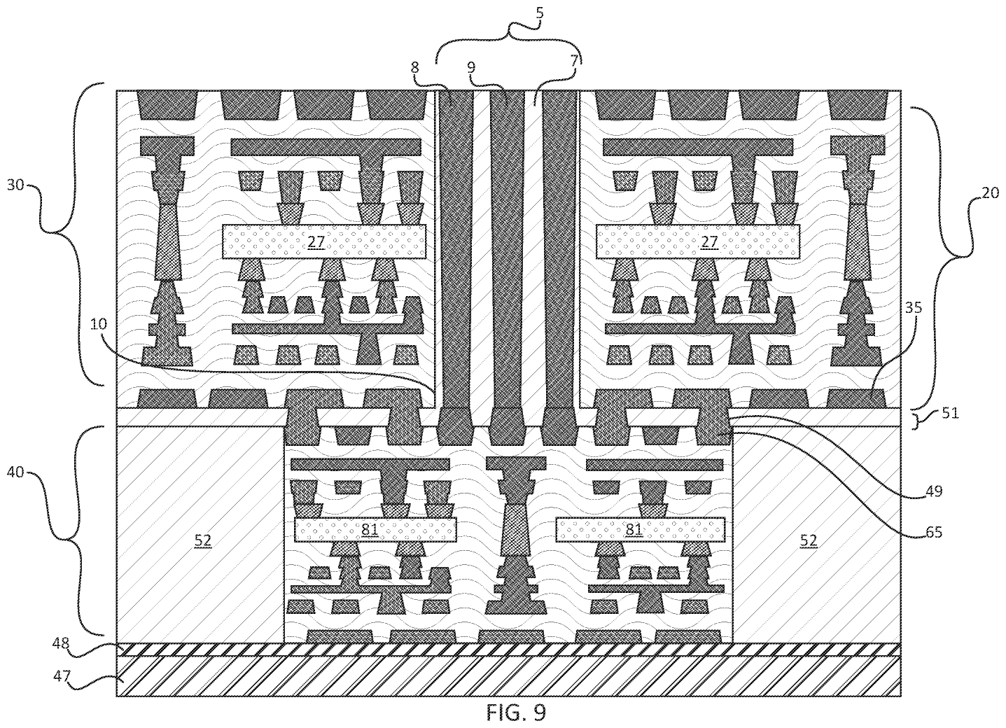

FIG. 8 illustrates an embodiment of coaxial through dielectric via patterning for a through insulator via (TIV) 10. Patterning may include forming a via mask 54. The via mask 54 may be a hardmask that is produced by depositing a hardmask material, and patterning the hardmask material using photolithography. After patterning, the hardmask material may be etched to the geometry of the via mask 54. The etch process may be an anisotropic etch, such as reactive ion etching (RIE). In some embodiments, the pattern and etch processes may produce at least two concentric openings. A first concentric opening 55 is produced by the etch process is subsequently filled with a metal to provide the signal via 9. A second concentric opening 56 that encircles the first concentric opening 55 produced by the etch process is subsequently filled to provide the ground shielding 8.

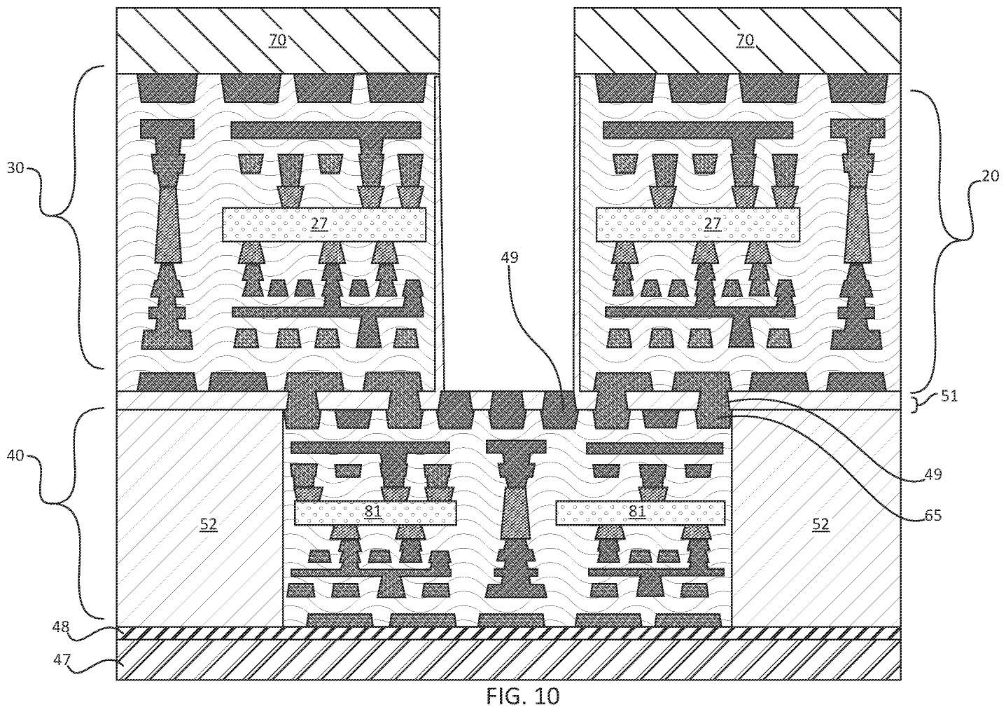

FIG. 9 illustrates an embodiment of filling the via openings with electrically conductive material, such as a metal, for the signal via 9 and the ground shielding 8 of the through insulator via (TIV) 10. The deposition process for the metal fill may include physical vapor deposition, such as sputtering, or plating, such as electroplating. The metal fill may also be deposited by chemical vapor deposition. A planarization process, such as chemical mechanical planarization, may be applied to the metal fill. The via mask 54 may be removed. The embodiment described with reference to FIGS. 8 and 9 can provide a signal via 9 and ground shielding 8 having the same composition of metal fill. The metal fill may include multiple layers of the same or different compositions for each of the signal via 9 and the ground shielding 8. The metal fill for the signal via 9 and the ground shielding 8 can also include liners, such as adhesion liners and diffusion barrier liners.

In a following process sequence, the structure depicted in FIG. 9 may be bonding to a device packaging substrate 59, as illustrated in FIG. 1. In some embodiments, solder ball 58 may be formed on the metal contacts of the first chiplet 20 and the second chiplet 30, as well as the exposed surfaces of the signal via 9 and the ground shielding 8. Thereafter, the solder balls 5 are thermally bonded to the device packaging substrate 59. An underfill may be employed to strengthen the bond. Further, the bilayer supporting carrier 53 may be removed, and replaced with thermal interface material (TIM) layer 60 and a lid 61.

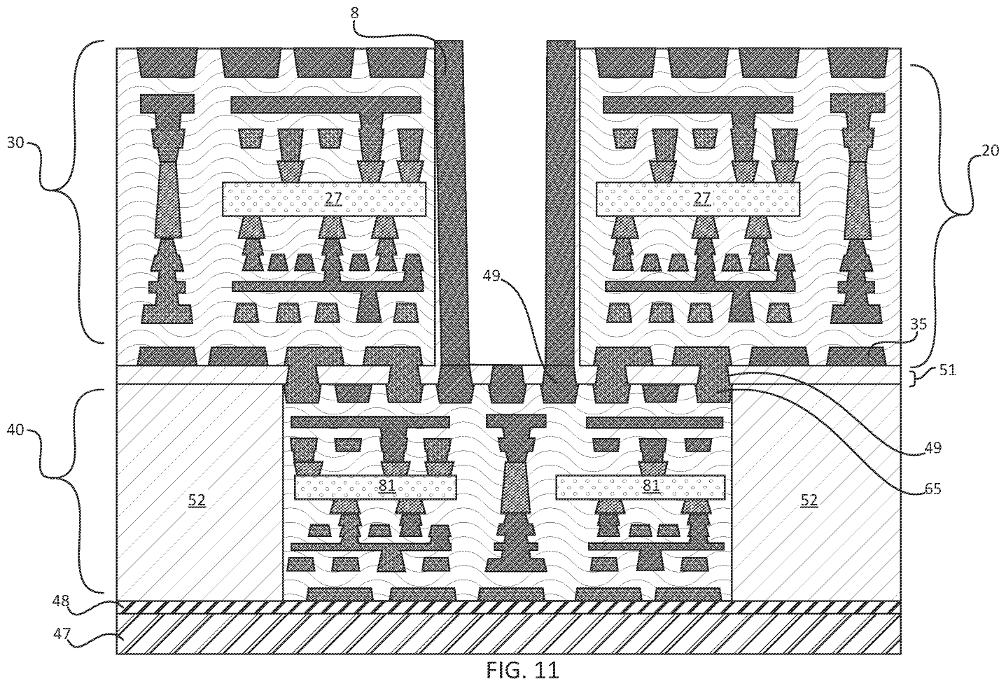

FIGS. 10-13 illustrate another embodiment of the present invention. In the embodiments depicted in FIGS. 10-13 the through insulator via 10 has a signal via 9 and ground shielding that have different metal compositions.

FIG. 10 illustrates an embodiment of coaxial through dielectric via patterning for a through insulator via (TIV) 10. The via opening formed in FIG. 10 differs from the method described above with reference to FIG. 8. Two separate via openings are formed using the method illustrated in FIG. 8. The method depicted in FIG. 10 only requires a single via opening for forming the through insulator via 10. Patterning may include forming a wide via mask 70. The wide via mask 70 may be a hardmask that is produced by depositing a hardmask material, and patterning the hardmask material using photolithography. After patterning, the hardmask material may be etched to the geometry of the wide via mask 70. The etch process may be an anisotropic etch, such as reactive ion etching (RIE). The wide via mask 70 can be removed.

FIG. 11 illustrates metal deposition into a via opening for a through insulator via (TIV), in which the metal being deposited provides ground shielding 8. The deposition process for the metal liner may include physical vapor deposition, such as sputtering, or plating, such as electroplating. An etch back process may be applied to remove any material that is not on a sidewall. The etch process may be an anisotropic etch, such as reactive ion etching (RIE). The metal deposited for the ground shielding 8 may be a multilayered structure, and can include liners, such as adhesion liners and/or diffusion barrier liners.

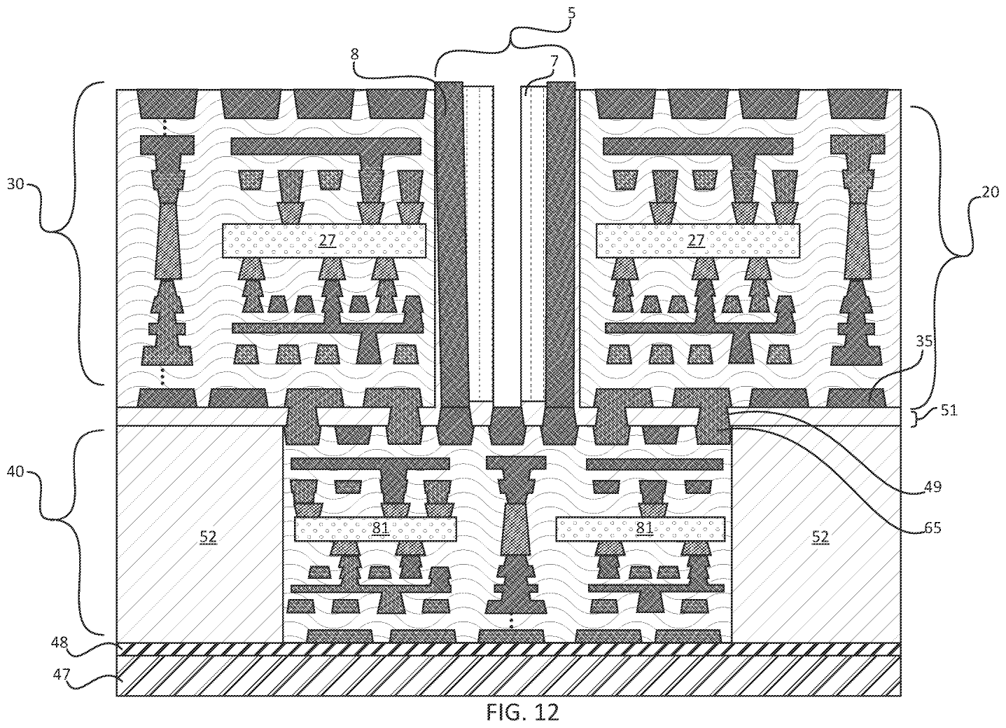

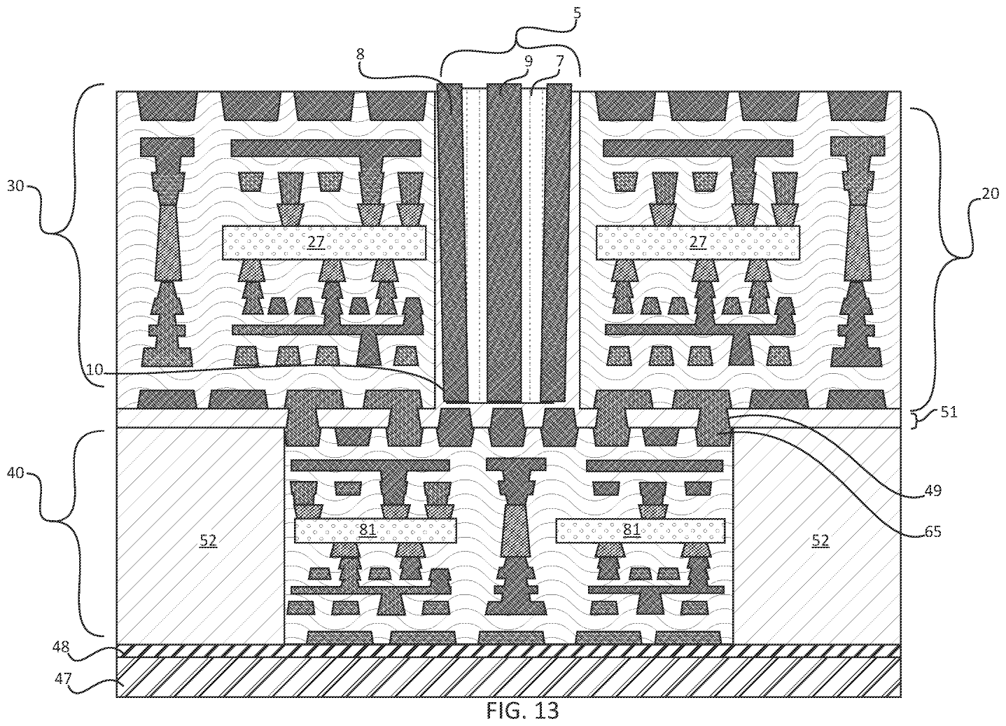

FIG. 12 illustrates forming a liner for the via dielectric 7 on the ground shielding 55. The liner may be deposited using a conformal deposition process followed by an etch back. The conformal deposition process may be chemical vapor deposition. The etch back process may be an anisotropic etch, such as reactive ion etching. The via dielectric 7 may be include multiple layers of dielectric material.

FIG. 13 illustrates an embodiment of filling the a remaining via openings with electrically conductive material, such as a metal, for the signal via 9. The deposition process for the metal fill may include physical vapor deposition, such as sputtering, or plating, such as electroplating. The metal fill may also be deposited by chemical vapor deposition. The metal deposited for the signal via 9 may be a multilayered structure, and can include liners, such as adhesion liners and/or diffusion barrier liners. A planarization process, such as chemical mechanical planarization, may be applied to the metal fill. The method depicted in FIGS. 10-13 allows for the signal via 9 and the ground shielding 8 to be formed using separate deposition steps. The embodiment described with reference to FIGS. 10-13 can provide a signal via 9 and ground shielding 8 having the different compositions for the metal fill.

In a following process sequence, the structure depicted in FIG. 13 may be bonding to a device packaging substrate 59, as illustrated in FIG. 1. In some embodiments, solder balls 58 may be formed on the metal contacts of the first chiplet 20 and the second chiplet 30, as well as the exposed surfaces of the signal via 9 and the ground shielding 8. Thereafter, the solder balls 5 are thermally bonded to the device packaging substrate 59. An underfill may be employed to strengthen the bond. Further, the bilayer supporting carrier 53 may be removed, and replaced with a thermal interface material (TIM) layer 60 and a lid 61.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of coaxial through insulator via between chiplets (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device comprising:
at least two chiplets separated by an insulating region; and
a through insulator via (TIV) extending through the insulating region, the through insulator via (TIV) including a coaxial arrangement of a signal via having ground shielding about a perimeter of the signal via, wherein the ground shielding is continuous from a first face of the insulating region to a second face of the insulating region.

2. The semiconductor device of claim 1, wherein the signal via is separated from the ground shielding by a via insulating material.

3. The semiconductor device of claim 2, wherein the insulating region has a first dielectric composition that is different from a second dielectric composition for the via insulating material.

4. The semiconductor device of claim 1, wherein the through insulator via (TIV) is connected to a bridge chip that is present on the at least two chiplets.

5. The semiconductor device of claim 1, wherein the through insulator via is in electrical communication with a redistribution layer on at least one of the first and second face of the insulating region, the redistribution layer being in electrical communication with one of the at least two chiplets.

6. The semiconductor device of claim 1, wherein the at least two chiplets includes two stacked levels of chiplets and the through insulator via is a skip via.

7. The semiconductor device of claim 1, wherein the through insulator via having the coaxial arrangement of the signal via having ground shielding about the perimeter of the signal via may be integrated with a power via that does not include ground shielding in the insulating region.

8. A semiconductor device comprising:
at least two chiplets separated by an insulating region; and
a through insulator via extending through the insulating region, the through insulator via including a coaxial arrangement of a signal via of a first metal composition having ground shielding of a second metal composition about a perimeter of the signal via, the first metal composition being different than the second metal composition, wherein the ground shielding is continuous from a first face of the insulating region to a second face of the insulating region.

9. The semiconductor device of claim 8, wherein the signal via is separated from the ground shielding by a via insulating material.

10. The semiconductor device of claim 9, wherein the insulating region has a first dielectric composition that is different from a second dielectric composition for the via insulating material.

11. The semiconductor device of claim 8, wherein the through insulator via (TIV) is connected to a bridge chip that is present on the at least two chiplets.

12. The semiconductor device of claim 8, wherein the through insulator via is in electrical communication with a redistribution layer on at least one of the first and second face of the insulating region, the redistribution layer being in electrical communication with one of the at least two chiplets.

13. The semiconductor device of claim 8, wherein the at least two chiplets includes two stacked levels of chiplets and the through insulator via is a skip via.

14. The semiconductor device of claim 8, wherein the through insulator via having the coaxial arrangement of the signal via having ground shielding about the perimeter of the signal via may be integrated with a power via that does not include ground shielding in the insulating region.

15. A semiconductor device comprising:
at least two chiplets separated by an insulating region; and
a through insulator via extending through the insulating region, the through insulator via including a coaxial arrangement of a signal via having ground shielding about a perimeter of the signal via, the signal via and the ground shield each having a same metal composition, wherein the ground shielding is continuous from a first face of the insulating region to a second face of the insulating region.

16. The semiconductor device of claim 15, wherein the signal via is separated from the ground shielding by a via insulating material.

17. The semiconductor device of claim 16, wherein the insulating region has a first dielectric composition that is different from a second dielectric composition for the via insulating material.

18. The semiconductor device of claim 15, wherein the through insulator via (TIV) is connected to a bridge chip that is present on the at least two chiplets.

19. The semiconductor device of claim 15, wherein the through insulator via is in electrical communication with a redistribution layer on at least one of the first and second face of the insulating region, the redistribution layer being in electrical communication with one of the at least two chiplets.

20. The semiconductor device of claim 15, wherein the at least two chiplets includes two stacked levels of chiplets and the through insulator via is a skip via.
